(19) United States
(12) Patent Application Publication
(10) Pub. No.: US 2010/0032661 A1
(43) Pub. Date: Feb. 11, 2010

(54) ORGANIC FIELD-EFFECT TRANSISTOR

(75) Inventors: Ronald Osterbacka, Abo (FI); Carl-Erik Wilen, Esbo (FI); Tomas Backlund, Tammerfors (FI); Nikolai Kaihovirta, Abo (FI)

Correspondence Address: YOUNG & THOMPSON, 209 Madison Street, Suite 500, Alexandria, VA, 22314, US

(73) Assignees: Ronald OSTERBACKA, Abo (FI); Carl-Erik WILEN, Esbo (FI)

(21) Appl. No.: 12/524,471

(22) PCT Filed: Jan. 23, 2008
(86) PCT No.: PCT/FI08/00015

§ 371 Date: Sep. 22, 2009

(30) Foreign Application Priority Data
Jan. 24, 2007 (FI) 20070063

(51) Int. Cl. H01L 51/30

(52) U.S. Cl. 257/40; 438/99; 257/E51.024

(57) ABSTRACT

An organic field-effect transistor includes between an organic semiconductor layer (203) and a gate electrode (204) a polymer membrane (205) having a ion-conducting spatial area (206) between a channel region and the gate electrode. Due to the ion-conducting spatial area (206) a distance between the gate electrode and the organic semiconductor layer can be longer than that in an organic field-effect transistor according to the prior art.

### FIELD OF THE INVENTION

The invention concerns generally organic field-effect transistors. Especially the invention takes advantage of appropriate selection of materials and manufacturing methods to achieve advantageous electrical properties for an organic field effect transistor as well as to achieve an advantageous mechanical structure of an organic field effect transistor.

### BACKGROUND OF THE INVENTION

The basic technology of organic field-effect transistors (OFET) is well known and established. FIG. 1 is a cross section through one basic OFET structure, known as the top-gate structure. The relative dimensions in the drawing are not realistic but were mainly chosen for reasons of graphical clarity. A substrate 101 constitutes a smooth, nonconductive support surface on which the other layers reside. On top of the substrate 101 there are source and drain electrodes 102 and 103 respectively, which are made of a highly conductive material, such as a thin metallic layer or a conductive polymer. An active layer 104 connects the source and drain electrodes 102 and 103 together. Some textbook sources also designate the active layer as the channel layer. The active layer 104 is made of semiconductive organic material; conjugated polymers are preferred.

On top of the active layer 104 there is an insulating layer 105, the purpose of which is to act as an electric insulator. Consequently the insulating layer 105 has good electric insulation properties, and is made of polymer (e.g. polystyrene) or inorganic material (e.g. SiO₂). Properties of an insulating layer that can be used in an OFET are described e.g. by Veres et al., in Chem. Mater. 2004, 16, 4543-4555. It is possible to build the insulating layer 105 from several component layers one upon the other, in order to acquire specific results such as surface modification, diffusion barrier or solvent compatibility. A gate electrode layer 106 lies on top of the insulating layer 105 and is made of metal or a highly conductive polymer. The structure also comprises various interconnect lines and contact pads connected to electrodes, but these are not shown in FIG. 1 in order to enhance graphical clarity.

The structure of FIG. 1 functions as a field-effect transistor so that an electrical potential difference between the gate 106 and the source 102 gives rise to a number of charge carriers within the active layer 104, which affects the possibility of an electric current to flow therethrough. In its simplest form the OFET of FIG. 1 functions as a switch, so that at one gate potential value an electric current may pass between the source and drain, while at another gate potential value electric current is kept from flowing. One of the central factors that affect the operation of an OFET is the inherent mobility of charge carriers in the channel material. Typically high mobility is aimed at, because high mobility of charge carriers in the channel translates as sensitivity in terms of a short switching time and a strong correlation between gate voltage and source-drain current.

A typical limitation of traditional OFETs is the fact that they require a relatively high electrical potential difference between the gate 106 and the source 102, often in excess of 10 volts, due to a low capacitance between the gate 106 and the active layer 104. Strength of an electrical field in the active layer 104 that gives rise to a number of charge carriers within the active layer 104 depends on a surface charge density (Coulomb/cm²) on the gate 106. The potential difference between the gate 106 and the source 102 is directly related to the strength of an electrical field in the insulator layer 105 and the thickness of said insulator layer. A certain electrical field in the active layer corresponds with a certain amount of electrical charge on the gate. There are two basic principles to reduce the potential difference between the gate and the source that corresponds with a certain amount of electrical charge on the gate, i.e. to increase the capacitance between the gate and the active layer. Firstly, a distance between the gate and the active layer is reduced, i.e. the insulating layer 105 is made thinner, and secondly, the electrical field in the insulating layer is mitigated by using insulating material with a high relative dielectric constant.

### DESCRIPTION OF THE PRIOR ART

The state of the art in OFET technology is discussed for example in publications US 2003/0059984 A1, WO02/095805, U.S. Pat. No. 6,380,558, U.S. Pat. No. 6,506,438, U.S. Pat. No. 6,429,450, WO99/10939 and U.S. Pat. No. 6,344,660. Additionally certain methods for manufacturing semiconductive thin film structures of OFETs are treated in EP-A1-0 701 290, U.S. Pat. No. 6,150,692 and US 2002/0158574 A1. It is possible to combine organic and inorganic materials in manufacturing thin film transistors, but the use of inorganic substances and small organic molecules tends to require complicated vacuum deposition processing and expensive machinery, which means loosing many advantages associated with organic materials that come in solutions.

Publication FI116704 discloses an OFET structure in which a hygroscopic polymer is used in a gate-insulating layer of an organic field-effect transistor and a polar solvent is allowed to be absorbed in said hygroscopic polymer to enhance operation of the organic field-effect transistor. Required gate-to-source voltages were reduced to below 2 volts when a polar solvent was present, e.g. moisture from the atmosphere. A corresponding OFET structure is described by T. G. Bäcklund et al., Journal of Applied Physics 98, 074504 (2005).

Publication Bard, E. & Faulkner, L. Electrochemical methods: Fundamentals and Applications (Wiley, New York 2001) discloses a solution in which a layer of polyelectrolyte, e.g. salt in a polymer matrix, is used between a gate electrode and an active semiconductor layer of an organic field-effect transistor. An electric double layer capacitance (EDLC) is formed between the gate electrode and the semiconductor layer. Such EDLCs have extraordinary high capacitance per unit area, e.g. 500 μF/cm² and are able to change their status of charge polarization quickly; within few tens of microseconds. Berggren et al. (Oral presentation at MRS Fall meeting, Boston December 2005) have shown that by using a polyelectrolyte an OFET can be operated with gate-to-source voltages less than 1 volt (Herlogsson et al., Advanced Materials 19:97-101 (2007), and Said E. et al., Applied Physics Letters, 89, 143507 (2006)). The EDLC can also be used to gate single crystal OFETs as shown by Shimotani H. et al., Applied Physics Letters, 89, 203501 (2006). A single crystalline OFET can be fabricated as shown in the review article by Tang et al., Progress in Chemistry 18 (11): 1538-1554 November 2006.

In organic field-effect transistors according to the prior art a layer between a gate electrode and an active semiconductor layer has to be relatively thin. For example, in publication FI116704 a suitable layer thickness is mentioned to be from 300 nm to 2000 nm. This fact causes limitations to a mechanical structure of an organic field-effect transistor. For example, a gate electrode and an active semiconductor layer cannot be located on opposite sides of an layer that constitutes a mechanical support of an organic field-effect transistor since the gate electrode and the active layer would be too far from each other. The gate electrode and the active semiconductor layer have to be aligned with each other usually on a μm scale. These facts complicate a manufacturing process of a thin film organic field-effect transistor.

### BRIEF DESCRIPTION OF THE INVENTION

An objective of the present invention is to provide an organic field-effect transistor such that drawbacks associated with the prior art are eliminated or reduced. A further objective of the present invention is to provide a manufacturing method for producing organic field-effect transistors according to the invention so that drawbacks associated with manufacturing methods according to the prior art are eliminated or reduced.

The objectives of the invention are achieved by providing a polymer membrane exhibiting ion-conductivity between a gate electrode and an organic semiconductor layer of an organic field-effect transistor. By careful preparation of the membrane, ion movements can be allowed in the membrane alone in the vicinity of the organic semiconductor layer. Therefore, a functional part of an electric double layer capacitance (EDLC) is able to be formed in the vicinity of the organic semiconductor layer. Thus an organic field-effect transistor according to the present invention can be operated with gate-to-source voltages less than 1 volt.

The ion-conductivity in polymer can be achieved with either positively charged mobile ions, e.g. H+, Li+, or with negatively charged mobile ions, e.g. Cl−, OH−.

Different patterns of ion-conducting spatial areas can be made into a polymer membrane using known manufacturing methods of ion-conducting polymers, e.g. by using an aligned electron beam (EB). It is also possible to realize a smooth or progressive change of ion-conductivity on a border region of a ion-conducting spatial area and a non-ion-conducting spatial area in a polymer membrane.

The invention yields appreciable benefits compared to prior art solutions. The benefits are discussed below.

A distance between a gate electrode and an organic semiconductor layer can be longer than that in an organic field-effect transistor according to the prior art. For example, in publication FI116704 a suitable distance between a gate electrode and an organic semiconductor layer is mentioned to be from 0.3 μm to 2 μm. In an organic field-effect transistor according to the present invention the above-mentioned distance can be even 100 μm. This fact opens a door for a mechanical structure in which a polymer membrane between a gate electrode and an active semiconductor constitutes a mechanical support of an organic field-effect transistor and no separate substrate is needed. It is, however, possible to use an additional mechanical support, e.g. cardboard to a surface of which an organic field-effect transistor can be attached.

Due to the above-mentioned mechanical structure a manufacturing process is simple. In an exemplary embodiment, only a gate electrode has to be produced on a first surface of a polymer membrane having one or more ion-conducting spatial areas. Drain and source electrodes and an organic semiconductor layer are produced on a second surface of said polymer membrane. In other words, there will be no more than two layers on top of each other per a side of a polymer membrane.

To fabricate an organic field-effect transistor according to the prior art one usually needs a very exact alignment of different layers, usually on a μm scale. A fact that a functional part of an electric double layer capacitance (EDLC) is able to be formed in the vicinity of the organic semiconductor layer makes an organic field effect transistor according to the present invention less sensitive to channel dimensions. Tests have shown that e.g. channel lengths of the order of hundreds of microns are workable. Therefore, the alignment of different layers in an organic field-effect transistor according to the present invention is less critical.

Electrical properties of an organic field-effect transistor according to the present invention can be tuned by tuning ion-conductivity value of an ion-conducting spatial area (areas) in a polymer membrane. For example, by increasing the ion-conductivity switching speed can be increased and by decreasing the ion-conductivity a peak value of a gate charging current can be reduced.

To make electronics, e.g. an active display, with transistors driving picture elements (pixels), one usually needs to make the electronics in several layers with via-holes and via-conductors to transfer signals between different layers. An organic field-effect transistor according to the present invention forms a natural via-path for a signal through a polymer membrane since a gate electrode is on a different side of the membrane than drain and source electrodes. It is also possible to create a capacitive via-path between two electrodes that are located on opposite surfaces of the polymer membrane. The impedance of the above-mentioned capacitive via-path can be made relatively low by arranging the polymer membrane to exhibit ion-conductivity between the two electrodes.

An organic field-effect transistor according to the invention comprises:
a source electrode and a drain electrode,
an organic semiconductor layer disposed to form a channel region between the source electrode and the drain electrode, and
a gate electrode;
   and the organic field-effect transistor is characterized in that it comprises between the organic semiconductor layer and the gate electrode a polymer membrane that exhibits ion-conductivity between the channel region and the gate electrode.

A method according to the invention for manufacturing an organic field-effect transistor is characterised in that the method comprises:
fabricating a polymer membrane at least a part of which exhibits ion-conductivity,
forming an organic semiconductor layer on a first side of said polymer membrane, and
forming a gate electrode on a second side of said polymer membrane to cover at least partly a projection of an ion-conducting spatial area of said polymer membrane, said projection being on a surface of said polymer membrane.

A number of embodiments of the invention are described in accompanied dependent claims.

Features of various advantageous embodiments of the invention are described below. The exemplary embodiments of the invention presented in this document are not to be interpreted to pose limitations to the applicability of the appended claims. The verb “to comprise” is used in this document as an open limitation that does not exclude the existence of also unrecited features. The features recited in depending claims are mutually freely combinable unless otherwise explicitly stated.

### BRIEF DESCRIPTION OF THE FIGURES

The invention and its other advantages are explained in greater detail below with reference to the preferred embodiments presented in the sense of examples and with reference to the accompanying drawings, in which

FIG. 1 is a schematic cross section of a field-effect transistor according to the prior art,

FIG. 2 is a schematic cross section of a field-effect transistor according to an embodiment of the invention,

FIGS. 3a and 3b illustrate operation of a field-effect transistor according to an embodiment of the invention,

FIG. 4 is a schematic cross section of a field-effect transistor according to an embodiment of the invention,

FIG. 5 is a schematic cross section of a field-effect transistor according to an embodiment of the invention,

FIGS. 6a and 6b show a schematic top view and a schematic cross section of an organic field-effect transistor according to an embodiment of the invention,

FIGS. 7a, 7b, and 7c are schematic cross sections of field-effect transistors according to embodiments of the invention,

FIGS. 8a, 8b, 8c, and 8d are schematic cross sections of field-effect transistors according to embodiments of the invention,

FIG. 9 is flow chart of a method according to an embodiment of the invention for manufacturing an organic field-effect transistor, and

FIGS. 10a-10e show measured dependencies of drain current on drain voltage for different gate voltages for organic field-effect transistors according to embodiments of the invention.

### DETAILED DESCRIPTION OF THE PREFERRED EMBODIMENTS OF THE INVENTION

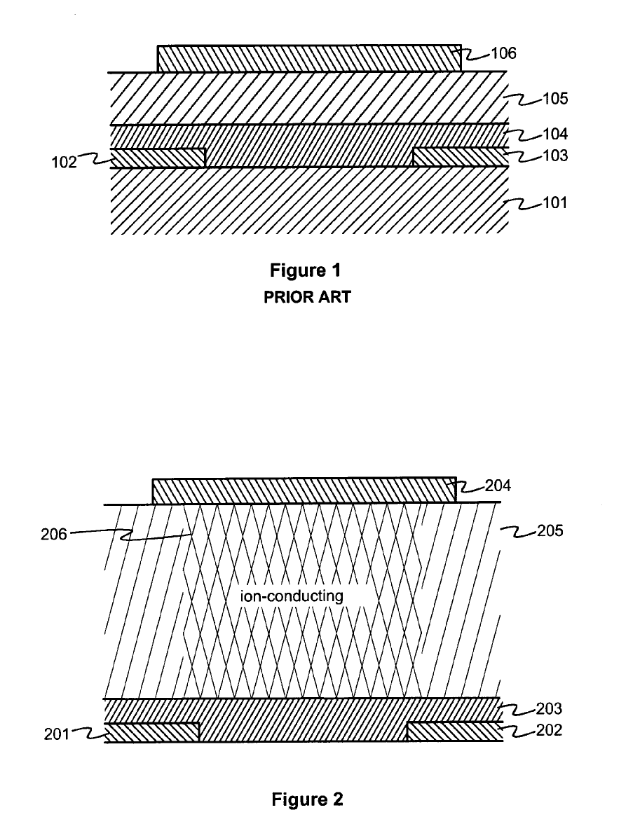

FIG. 1 has been explained above in the description of prior art.

FIG. 2 illustrates a schematic cross section of a field-effect transistor according to an embodiment of the invention. The organic field-effect transistor comprises a source electrode 201 and a drain electrode 202, an organic semiconductor layer 203 disposed to form a channel region between the source electrode and the drain electrode, a gate electrode 204, and between the organic semiconductor layer and the gate electrode a polymer membrane 205 having an ion-conducting spatial area 206 between the channel region and the gate electrode. The ion-conducting spatial area is shown in FIG. 2 as a cross-hatched area. The relative dimensions in the drawing are not realistic but were mainly chosen for reasons of graphical clarity.

In an organic field-effect transistor according to an embodiment of the invention the polymer membrane 205 is paper impregnated with ion-conducting liquid.

In an organic field-effect transistor according to an embodiment of the invention the polymer membrane 205 is paper made of sulfonated natural fibers. In this case the ion-conductivity is achieved by sulfonating the fibers before producing the paper.

Both natural and synthetic fibers can be used for producing a polymer membrane that exhibits ion-conductivity. A more detailed description is presented in a later part of this document.

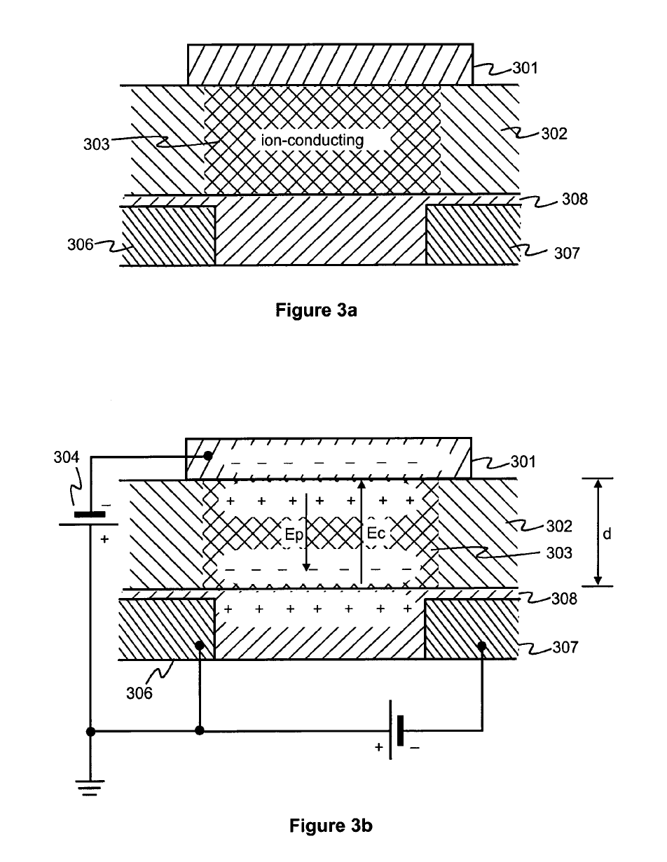

FIGS. 3a and 3b illustrate operation of a field-effect transistor according to an embodiment of the invention. FIG. 3a corresponds with a situation in which there is no (net) electrical charge in a gate electrode 301. Mobile ions are arranged in an ion-conducting spatial area 303 of a polymer membrane 302 in such a way that there is no sub-area that would have a positive net charge and no sub-area that would have a negative net charge. FIG. 3b corresponds with a situation in which there is a negative (net) electrical charge in the gate electrode 301. The negative charge on the gate electrode is provided with a voltage source 304. If the ion-conductivity in the polymer membrane is achieved with positively charged mobile ions, the negative charge on the gate electrode 301 attracts the mobile positive ions of the ion-conducting spatial area 303 to an upper part of the ion-conducting spatial area 303. Therefore, there will be a lack of mobile positive ions in a lower part of the ion-conducting spatial area 303. If the ion-conductivity in the polymer membrane is achieved with negatively charged mobile ions, the negative charge on the gate electrode 301 repulses the mobile negative ions of the ion-conducting spatial area 303 to the lower part of the ion-conducting spatial area 303. Therefore, there will be a lack of mobile negative ions in the upper part of the ion-conducting spatial area 303. In both of the above-mentioned cases a negative net charge is formed in said lower part and a positive net charge is formed in said upper part. Areas having a positive net charge are marked with ‘+’ marks and areas with negative net charge are marked with ‘−’ marks. The negative net charge in the lower part of ion-conducting spatial area 303 attracts a positive net charge to a channel region between a source electrode 306 and a drain electrode 307 in an organic semiconductor layer 308.

Functional parts of an electric double layer capacitance (EDLC) are formed in a border zone between the gate electrode 301 and the polymer membrane 302 and in a border zone between the polymer membrane 302 and the organic semiconductor layer 308.

A voltage between the gate electrode 301 and the organic semiconductor layer 308 is approximately:

$$Vg = d \times ( Ec - Ep \frac{d p}{d} ) \qquad ( 1 )$$

where Ec is average electric field strength (V/m) caused by charge polarization Qg between the gate electrode 301 and the organic semiconductor layer 308, Ep is average electric field strength caused by internal charge polarization in the ion-conducting spatial area 303, d is a thickness of the polymer membrane 302, and dp is an effective polarization distance inside the ion-conducting spatial area 303. If there were no mobile charge carriers in the ion-conducting spatial area 303 the voltage Vg would be approximately Ec×d that is a higher value than that in equation (1). When the ion-conductivity is so high that the net-electrical field (Ec−Ep) inside the ion-conducting spatial area 303 is substantially zero, i.e. Ec≈Ep, the voltage Vg is substantially Ec×(d−dp). The difference d−dp can be kept constant when the thickness of the polymer membrane 302 is varied. Therefore, the voltage Vg that corresponds with certain electrical field strength Ec directed to the organic semiconductor layer 308 is substantially independent of the thickness d of the polymer membrane 302. Therefore, organic field effect transistors of the kind described above, which have different thicknesses of the polymer membrane 302, can be operated with substantially similar gate voltages Vg.

As can be seen use of the ion-conducting spatial area 303 reduces significantly (an absolute value of) the gate voltage that is needed to make the channel region between a source electrode 306 and the drain electrode 307 electrically conductive. In other words, a gate capacitance is increased since a ratio Qg/Vg constitutes a value of the gate capacitance of an organic field-effect transistor.

Operation of an organic field effect transistor according to an embodiment of the invention can be improved by utilizing an electrochemical process that occurs in an organic semiconductor where salt or corresponding ions are present. The electrochemical process can be described as:

polymer+C⁺A⁻ [symbol] polymer⁺A⁻+C⁺+e⁻, (2)

where “polymer” is a conjugated polymer, C is a cation, A is an anion, e is an electron and the plus and minus superscripts designate electric charge. From left to right equation (2) means that a salt gets dissociated into ions, an anion and a cation, in the presence of moisture or other factor facilitating the dissociation mechanism. The anion oxidizes the polymer chain, and a cation and an electron are left free. The conjugated polymer is left in an oxidized state, which typically means that it becomes more conductive. The cation is either trapped in the material or moves freely within the structure under the influence of the prevailing electric field. Salts and/or ions are present due to intentional doping. Unintentional doping is also likely to result from residues from polymer synthesis as well as contamination during processing.

The electrochemical processes are fully reversible and an equilibrium state is reached after a time that depends on the electric field within the polymer as well as the concentrations of the different species. In the equilibrium state transitions from a state corresponding with the left hand side of equation (2) to a state corresponding with the right hand side of equation (2) occur, in the sense of time average, at a same rate as corresponding transitions in the opposite direction. The position of the equilibrium state between a theoretical extreme in which all salt molecules are in an ionized state and another theoretical extreme in which all salt molecules are in a non-ionized state, is determined partly by an electric field applied to the organic semiconductor. Therefore, the electrical conductivity of the channel region in the organic semiconductor layer 308 can be altered by altering a value of electric field applied to said channel region.

In an organic field-effect transistor according to an embodiment of the invention the organic semiconductor layer 308 is made of RR—P3HT (regioregular poly(3-hexylthiophene)), which is a polymeric semiconductor, and the gate electrode 301 is made of PEDOT:PSS (poly(2,3-dihydrothieno-[3,4-b]-1,4-dioxin) and poly(styrenesulfonate)), which is a conductive polymer. Depending on the applied naming standard, PEDOT is also known as poly(dihydrothienodioxine) or polyethylenedioxythiophene. RR—P3HT should not be confused with regiorandom poly(3-hexylthiophene), for which the simplified notation PHT is typically used. On the other hand, from the viewpoint of the present invention all regioregular poly(alkyl-thiophene)s are believed to be suitable for the organic semiconductor layer 308. In this embodiment PEDOT (poly(2,3-dihydrothieno-[3,4-b]-1,4-dioxin)) is used together with PSS (poly(styrenesulfonate)). This makes it useful as an electric conductor regardless of small changes in the redox state of the material that may arise from electrochemical processes. The combination name PEDOT:PSS is frequently used.

In an organic field-effect transistor according to an embodiment of the invention the material of which the organic semiconductor layer 308 is formed is a polyfluorene derivative, e.g. poly(9,9-dioctylfluorene-co-bithiophene) alternating copolymer (F8T2) or poly[2,7-(9,9-di-n-octylfluorene)-alt-(1,4-phenylene-((4-sec-butylphenyl)amino)-1,4-phenylene)] (TFB).

Other examples of materials that can be used as the organic semiconductor layer 308 can be found in the publication: Singh and Sariciftci, Progress in Plastic Electronic Devices, Annu. Rev. Mater. Res. 2006, 36:199-230, which is herein incorporated by reference.

For a person skilled in the art it is clear that there are a wide variety of materials that can be used as the organic semiconductor layer 308 in an organic field-effect transistor according to an embodiment of the invention. Therefore the invention is not limited to the examples mentioned above and in the referred publications.

In an organic field-effect transistor according to an embodiment of the invention the source and drain electrodes 306 and 307 are made of thin metal films, for example gold, silver or aluminum, or of conductive polymers such as doped PANI (polyaniline). Generally any material forming an essentially galvanic contact with the semiconductor material can be used.

In an organic field-effect transistor according to an embodiment of the invention the gate electrode 301 is made of a thin metal film, for example gold, silver or aluminum, or of doped PANI (polyaniline).

In an organic field-effect transistor according to an embodiment of the invention the ion-conductivity is achieved with positively charged mobile ions, e.g. H+, Li+ (cation exchange).

In an organic field-effect transistor according to an embodiment of the invention the ion-conductivity is achieved with negatively charged mobile ions, e.g. Cl−, OH− (anion exchange).

In an organic field-effect transistor according to an embodiment of the invention the ion-conductive spatial area 303 of the polymer membrane 302 is a proton conductive spatial area such that negatively charged anions are covalently linked to a molecular structure of the polymer membrane 302 and positively charged H+ ions are mobile.

In an organic field-effect transistor according to an embodiment of the invention the organic semiconductor layer 308 is optically transparent with a band gap larger than 2.3 eV. Preferably, the band gap is larger than 2.5 eV.

In an organic field-effect transistor according to an embodiment of the invention the organic semiconductor layer 308 has an ionization potential larger than 4.9 eV.

In an organic field-effect transistor according to an embodiment of the invention the organic semiconductor layer 308 has an ionization potential larger than 5.1 eV.

In an organic field-effect transistor according to an embodiment of the invention the organic semiconductor layer 308 comprises a block copolymer comprising a first block of conjugated monomer units each linked by at least two covalent bonds, and a second block of monomer units, the block copolymer having an electron affinity greater than 3.0 eV or 3.5 eV.

In an organic field-effect transistor according to an embodiment of the invention the organic semiconductor layer 308 comprises a block copolymer comprising a first block of conjugated monomer units each linked by at least two covalent bonds, and a second block of monomer units, the block copolymer having an ionization potential in the range from 5.5 eV to 4.9 eV.

In an organic field-effect transistor according to an embodiment of the invention an ion-conducting spatial area extends through a polymer membrane and is surrounded by insulating spatial areas of the polymer membrane in directions that are in the plane of the polymer membrane. In directions perpendicular to the plane of the membrane the ion-conducting spatial area abuts on a gate electrode and on an organic semiconductor layer. This kind of embodiment is shown in FIGS. 2, 3a, and 3b if the ion-conducting spatial area abuts on the insulating spatial area of the polymer membrane also in the directions that are perpendicular to the planes of the figures. In FIGS. 2, 3a, and 3b the plane of the polymer membrane is perpendicular to the plane of the figures.

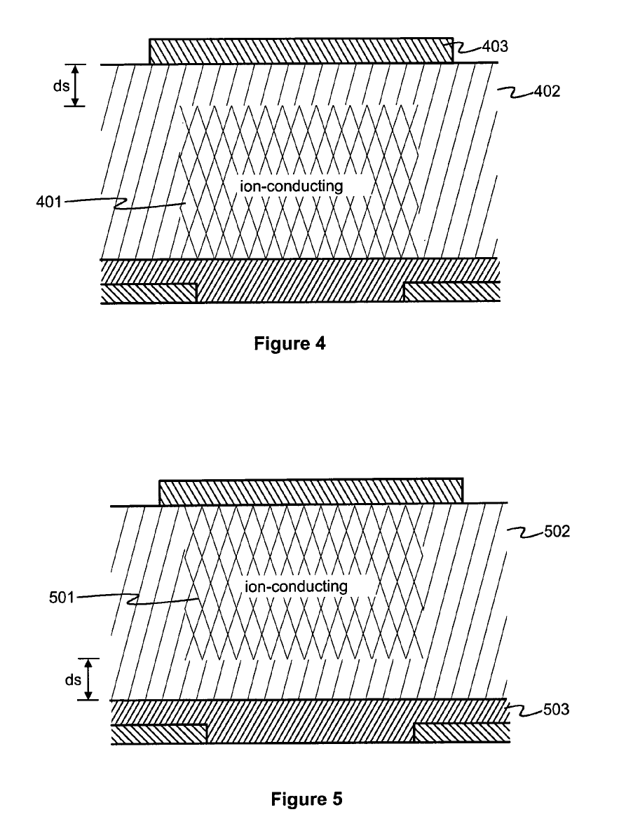

FIG. 4 shows a schematic cross section of a field-effect transistor according to an embodiment of the invention. In this embodiment of the invention an ion-conducting spatial area 401 is surrounded by insulating spatial areas of the polymer membrane 402 in directions that are in the plane of the polymer membrane and there is an insulating spatial area of the polymer membrane between a gate electrode 403 and the ion-conducting spatial area. The ion-conducting spatial area is shown in FIG. 4 as a cross-hatched area.

FIG. 5 shows a schematic cross section of a field-effect transistor according to an embodiment of the invention. In this embodiment of the invention an ion-conducting spatial area 501 is surrounded by insulating spatial areas of the polymer membrane 502 in directions that are in the plane of the polymer membrane and there is an insulating spatial area of the polymer membrane between an organic semiconductor layer 503 and the ion-conducting spatial area. The ion-conducting spatial area is shown in FIG. 5 as a cross-hatched area.

In an organic field effect transistor according to FIG. 4 or FIG. 5 a gate voltage needed to operate the organic field effect transistor depends on thickness of an insulating spatial area between a gate electrode and an organic semiconductor layer. The thickness of the insulating spatial area is denoted by ds in FIGS. 4 and 5. The thicker is the insulating spatial area the bigger is the gate voltage needed for operating the transistor. This is at least partly due to the fact that a ratio of an effective polarization distance inside the ion-conducting spatial area to the thickness of a polymer membrane, dp/d in equation (1), is decreased when the thickness ds is increased.

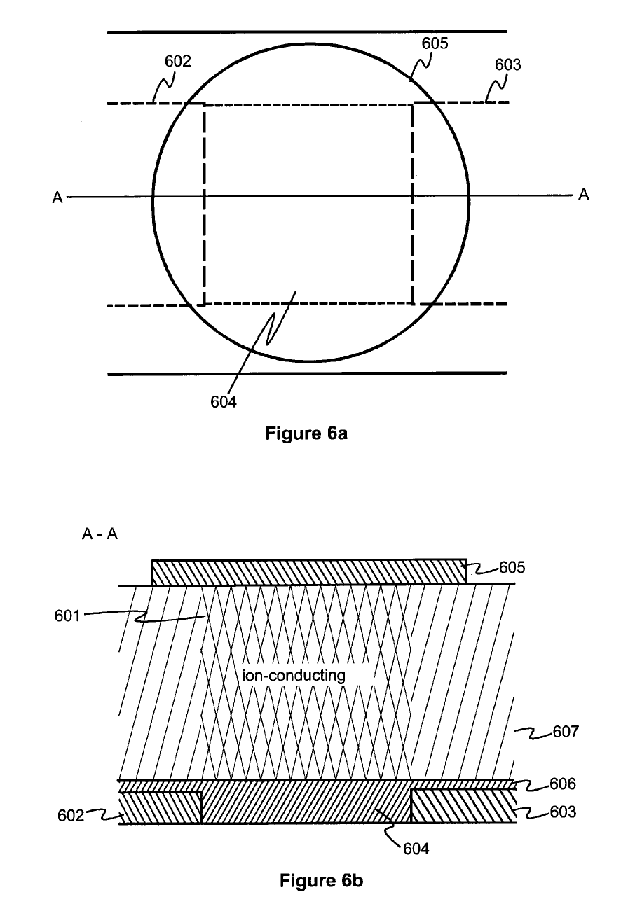

FIG. 6a shows a schematic top view of an organic field-effect transistor according to an embodiment of the invention. FIG. 6b shows a schematic cross section of said organic field-effect transistor. An ion-conducting spatial area 601 is disposed to be within a coverage area of a channel region 604 between a source electrode 602 and a drain electrode 603 in directions that are in the plane of a polymer membrane 607. The plane of the polymer membrane coincides with the figure plane of FIG. 6a. The ion-conducting spatial area is shown in FIG. 6b as a cross-hatched area. An advantage of this embodiment is the fact that parasitic capacitances between a gate electrode 605 and other areas of an organic semiconductor layer 606, between the gate electrode and a drain electrode, and between the gate electrode and a source electrode are not disturbingly big even if the gate electrode extends over the area of the channel region 604. This is due to the fact that a capacitance per unit area (Farad/cm²) is very small outside the coverage of the ion-conducting spatial area.

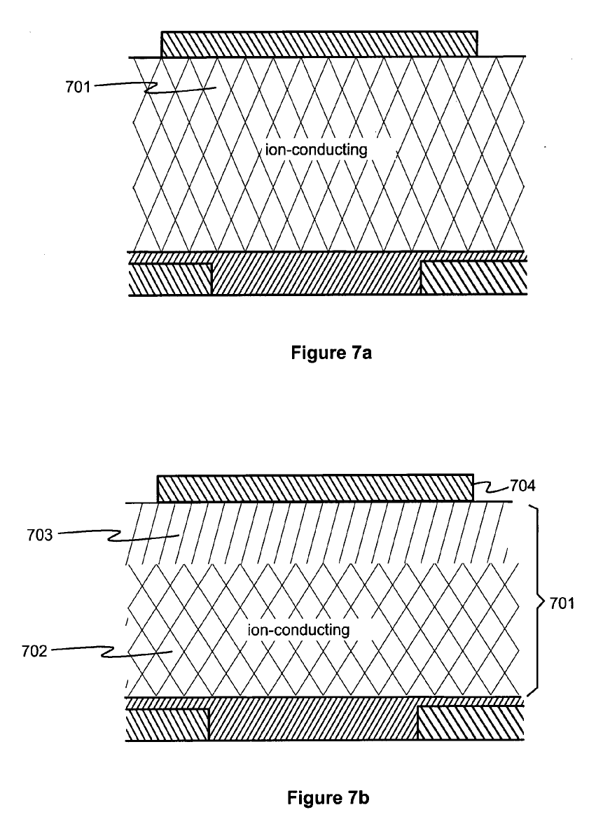

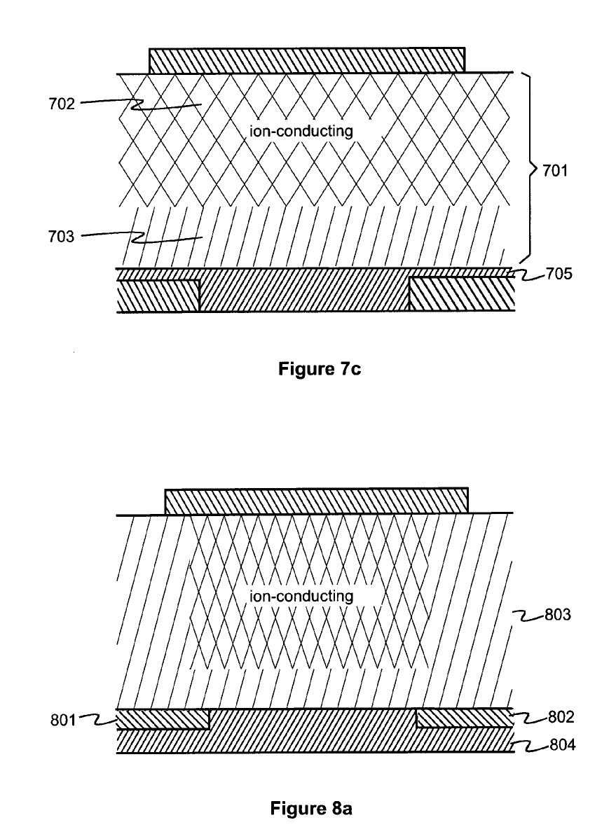

FIG. 7a shows a schematic cross section of a field-effect transistor according to an embodiment of the invention. In this embodiment a whole volume of a polymer membrane 701 is an ion-conducting spatial area. In other words, there is an ion-conducting polymer membrane. The ion-conducting spatial area is shown in FIG. 7a as a cross-hatched area.

FIG. 7b shows a schematic cross section of a field-effect transistor according to an embodiment of the invention. In this embodiment there is an insulating spatial area 703 of a polymer membrane 701 between a gate electrode 704 and an ion-conducting spatial area 702 of the polymer membrane. The polymer membrane has two layers. One of the layers represents the ion-conducting spatial area and another of the layers represents the insulating spatial area. The ion-conducting spatial area is shown in FIG. 7b as a cross-hatched area.

FIG. 7c shows a schematic cross section of a field-effect transistor according to an embodiment of the invention. In this embodiment there is an insulating spatial area 703 of a polymer membrane 701 between an organic semiconductor layer 705 and an ion-conducting spatial area 702 of the polymer membrane. The polymer membrane has two layers. One of the layers represents the ion-conducting spatial area and another of the layers represents the insulating spatial area. The ion-conducting spatial area is shown in FIG. 7c as a cross-hatched area.

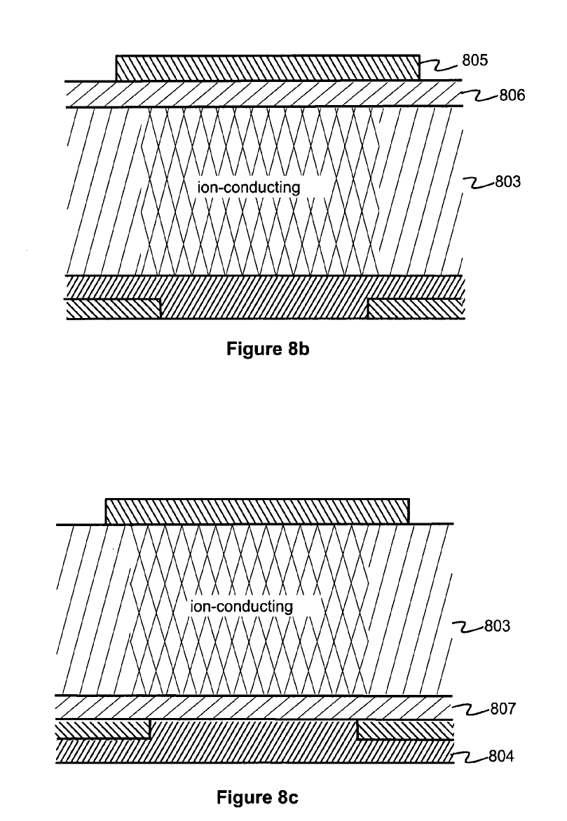

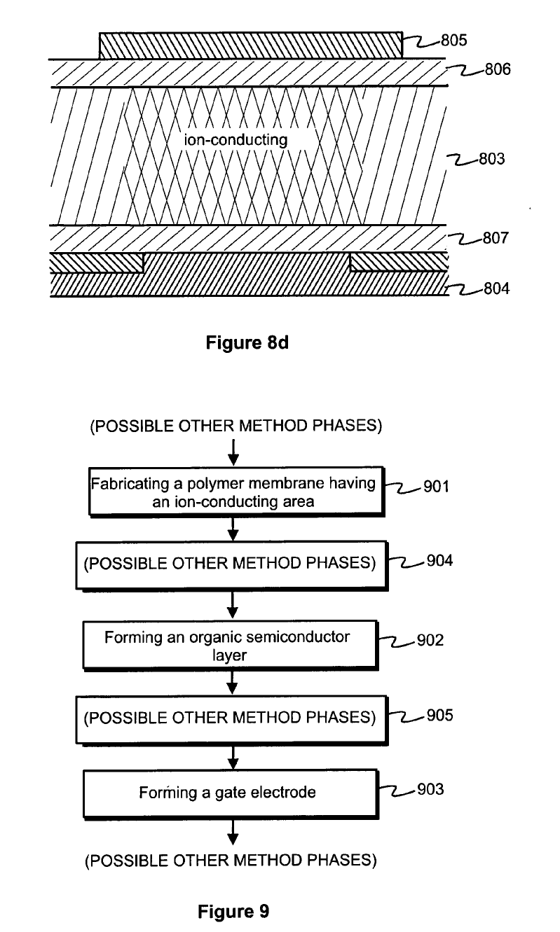

FIG. 8a shows a schematic cross section of a field-effect transistor according to an embodiment of the invention. In this embodiment of the invention a source electrode 801 and the drain electrode 802 are disposed to be between an organic semiconductor layer 804 and insulating spatial areas of a polymer membrane 803. An ion-conducting spatial area of the polymer membrane is shown in FIG. 8a as a cross-hatched area.

An advantage of an arrangement in which the ion-conducting spatial area is not in a direct contact with the surrounding atmosphere is the fact that ion-conducting material is protected against harmful effects of the surrounding atmosphere, e.g. against undesired effects of humidity. This kind of arrangement is shown e.g. in FIGS. 6a and 6b.

FIG. 8b shows a schematic cross section of a field-effect transistor according to an embodiment of the invention. The organic field-effect transistor according to this embodiment of the invention comprises an ion-blocking layer 806 between a gate electrode 805 and a polymer membrane 803. The ion-blocking layer prevents mobile ions of the polymer membrane from getting into contact with the gate electrode. An ion-conducting spatial area of the polymer membrane is shown in FIG. 8b as a cross-hatched area.

FIG. 8c shows a schematic cross section of a field-effect transistor according to an embodiment of the invention. The organic field-effect transistor according to this embodiment of the invention comprises an ion-blocking layer 807 between an organic semiconductor layer 804 and a polymer membrane 803. The ion-blocking layer prevents mobile ions of the polymer membrane from getting into contact with the organic semiconductor layer. An ion-conducting spatial area of the polymer membrane is shown in FIG. 8c as a cross-hatched area.

FIG. 8d shows a schematic cross section of a field-effect transistor according to an embodiment of the invention. The organic field-effect transistor according to this embodiment of the invention comprises a first ion-blocking layer 806 between a gate electrode 805 and a polymer membrane 803, and a second ion-blocking layer 807 between an organic semiconductor layer 804 and the polymer membrane 803. An ion-conducting spatial area of the polymer membrane is shown in FIG. 8d as a cross-hatched area.

FIG. 9 shows flow chart of a method according to an embodiment of the invention for manufacturing an organic field-effect transistor. In phase 901 a polymer membrane having an ion-conducting spatial area is fabricated. In phase 902 an organic semiconductor layer is formed on a first side of said polymer membrane. In phase 903 a gate electrode is formed on a second side of said polymer membrane to cover at least partly a projection of said ion-conducting spatial area on a surface of said polymer membrane.

It is possible to form more than one organic field-effect transistor according to an embodiment of the invention onto one polymer membrane. In this kind of case it is advantageous if each transistor has a transistor-specific separate ion-conducting spatial area in order to prevent mutual interactions between the transistors. On the other hand, a manufacturing process can be simpler if the whole membrane is ion-conducting.

A method according to an embodiment of the invention comprises forming a source electrode and a drain electrode on a surface of the organic semiconductor layer. In this case the block 905 in FIG. 9 can comprise the forming of the source electrode and the drain electrode on the surface of the organic semiconductor layer. A schematic cross section of an organic field-effect transistor manufactured using the method according to this embodiment of the invention is shown for example in FIG. 7.

A method according to an embodiment of the invention comprises forming a source electrode and a drain electrode on a surface of the polymer membrane on the first side of the polymer membrane. In this case the block 904 in FIG. 9 can comprise the forming of the source electrode and the drain electrode on the surface of the polymer membrane on the first side of the polymer membrane. A schematic cross section of an organic field-effect transistor manufactured using the method according to this embodiment of the invention is shown in FIG. 8.

A method according to an embodiment of the invention involves applying a printing technique with a polymer solution in order to form at least one of the following: the organic semiconductor layer and the gate electrode.

A method according to an embodiment of the invention involves using an unpurified polymer in the forming the organic semiconductor layer. In this case the presence of at least a part of salts and/or ions in the organic semiconductor layer is called unintentional doping.

In a method according to an embodiment of the invention the ion-conductivity is achieved with positively charged mobile ions, e.g. H+, Li+ (cation exchange).

In a method according to an embodiment of the invention the ion-conductivity is achieved with negatively charged mobile ions, e.g. Cl−, OH− (anion exchange).

A polymer membrane that exhibits ion-conductivity can be produced for example in the following ways:
1) starting with a monomer containing ion exchange group, which can be homopolymerized or copolymerized with non-functionalized monomer to eventually form an ion exchange membrane (e.g. by casting),
2) starting with polymer particles, which can be modified by introducing ion exchange groups and which are then embedded in a polymer binder and processed to make a foil,
3) starting from a film, which can be modified by introducing ionic characters either directly by grafting of functional monomer or indirectly by grafting of non-functional monomer followed by functionalization reaction,
4) blending of various polymers e.g. by acid-base blending,
5) producing a membrane of organic-inorganic composites that comprise primarily of a polymer and an inorganic proton conducting particle as outlined by A. Herring, Journal of Macromolecular Science, Part C: Polymer Reviews, 46:245-296, 2006, and
6) using porous polymer films that are impregnated with ion-conducting liquid.

Both natural and synthetic fibers can be used for producing a polymer membrane that exhibits ion-conductivity. The ion-conductivity can be achieved e.g. by sulfonating the fibers before producing the membrane and/or by impregnating the membrane with ion-conducting liquid. Paper constitutes an example of a polymer membrane that is made of natural fibers and that can be made ion-conductive by impregnating with ion-conducting liquid. It is also possible to sulfonate the natural fibers that are used for producing paper.

If the membrane material is made from only ion-exchange material, it is called a homogeneous ion-exchange membrane. If the ion-exchange material is embedded in an inert binder, it is called a heterogeneous ion-exchange membrane.

In a bipolar membrane a combination of cationic and anionic fixed groups are laying back to back on a polymer backbone. Whereas, the mosaic membrane is a polymer film carrying an array of anion and/or cation exchange domains separated by neutral regions.

The ion-conductivity of the membrane can be tailored by regulating the concentration of the fixed ions and their location. In the case of cation-exchange membranes the ion conductivity can e.g. be tailored by using acid that has a suitable acid dissociation constant (pKₐ). Thus, the cationic character is weak for membranes containing e.g. carboxylic acid groups and strong for those containing sulfonic groups. In the case of anionic exchange functional groups they can be either strongly basic such as quaternary ammonium or weakly basic such as primary, secondary or tertiary groups. Speed of an organic field-effect transistor according to an embodiment of the invention can be tailored by tuning the ion-conductivity

Typical examples of organic cation or anionic exchange ion-conductive membranes can be found in the following publications: M. Rikukawa, K. Sanui, Progress in Polymer Science 25 (2000) 1463-1502; M. M. Nasef, E-S. A. Hegazy, Progress in Polymer Science 29 (2004), 499-561; T. deV. Naylor, Polymer Membranes-Materials, Structures and Separation Performance, Rapra Review Reports, Volume 8, Number 5, 1996). The cationic-exchange membranes may contain e.g. the following fixed charges: —SO₃⁻, —COO⁻, —PO₃⁻, —AsO₃⁻², SeO₃⁻, etc. Anionic-exchange membranes may contain e.g. the following fixed charges: —NH₃⁺, —RNH₂⁺, —R₃N⁺, —R₃P⁺, —R₂S⁺, etc.

Also commercially available membranes such as Nafion (Du Pont) and other structurally analogues materials (Aciplex, XUS Dow, Flemion) are also suitable membranes for constructing an organic field-effect transistor according to an embodiment of the invention.

Gel-type of polymer electrolytes having high ionic conductivity have been developed by hosting a liquid solution of e.g. a lithium salt containing aprotic polar solvents such as ethylene carbonate (EC) and diethyl carbonate (DEC) in a polymer matrix.

Noteworthy, is that ion-conductivity can be obtained in both hydrous and anhydrous conditions. For anhydrous operations membranes containing lithium salt or imidazole moieties are advantageous but not to be interpreted to pose limitations.

In a method according to an embodiment of the invention the ion-conductive spatial area of the polymer membrane is a proton conductive spatial area such that negatively charged anions are covalently linked to a molecular structure of the polymer membrane and positively charged H+ ions are mobile.

The polymer membrane having a proton conducting spatial area can be fabricated as follows: In the first step an insulating PVDF-membrane (poly(vinylidene fluoride)) of 80 μm thickness is radiated with an electron beam and then the free radicals formed are immediately quenched with TEMPO (2,2,6,6-tetramethyl-piperidinyl-1-oxy). In the second step, the produced TEMPO-capped macroinitiator sites are utilized in nitroxide-mediated living free radical graft polymerization of styrene (30% degree of grafting) onto the PVDF-membrane. In the third and final step the membrane is directly sulfonated. Alternatively one may directly graft a monomer that contains e.g. a sulfonic acid group or a salt thereof onto the PVDF-membrane. The above-described grafting technique that combines conventional radiation-induced grafting with living free radical polymerization permits the production of well-defined graft homopolymers, block polymers, or polymers containing functional groups, e.g. the following fixed charges: —SO₃⁻, —COO⁻, —PO₃⁻, etc, at a specific loci either at chain ends, along the grafted backbone itself, or at specific areas of the membrane surface or bulk. Thus, this technique allows also patterning of the proton conducting spatial area (areas) in the membrane in order to tune a performance of an organic field effect transistor according to an embodiment of the invention. The grafting can be conducted in the manner that monomers are grafted through the membrane or alternatively only on one side of the membrane. In other words, membranes may be homogeneous or heterogeneous, symmetrical or asymmetrical, and porous or non-porous. A membrane can also be reinforced or it can be self-supporting. In this document the above-described fabrication technology is called an electron beam method.

Proton conductivity of a membrane can be tailored by regulating a concentration of fixed ions and their locations or by using an acid with a suitable acid dissociation constant (pKₐ). Other important factors that govern the membrane performance include an overall membrane morphology, an hydrophobic/hydrophilic balance of a polymer matrix, distribution of polar ionic groups within an hydrophobic matrix, and distribution of charge density, i.e. whether or not ion-exchange groups are in continuous contacts. Speed of an organic field-effect transistor according to an embodiment of the invention can be tailored by tuning the proton conductivity.

The above-described membrane fabrication technologies are just examples of feasible preparation technologies that can be utilized in a method according to an embodiment of the invention for manufacturing an organic field-effect transistor. There are a great number of fabrication technologies that can be utilized in methods according to different embodiments of the invention.

A person skilled to art can understand that various etching methods, direct sulfochlorination of a bulk polymer such as PE (polyethylene) with subsequent hydrolysis, radiation grafting with gamma-ray irradiation of a bulk polymer, plasma induced membrane modification, or some other state-of-art technology may also be utilized for fabricating polymer membranes having an ion-conducting spatial area. It is also possible to directly prepare polymer membranes via copolymerization of suitable monomers and to mix a commercial ion exchanger with a solution of polymer binder such as PVC (poly (vinyl chloride)), PE, PVDF, or rubber.

### EXPERIMENTAL EXAMPLES

### Example 1

In the first example a polymer membrane that exhibits ion-conductivity was produced in the following way.

PVDF-film were cut to samples of approx 5 cm×4 cm and extracted with chloroform for at least 2 hours in order to remove surface impurities. The samples were cut into smaller pieces, weighed and irradiated using an electron beam apparatus (EB). The samples were flushed with nitrogen during the irradiation procedure. After irradiation the samples were handled in a small nitrogen-flushed glove-box attached to the EB. The irradiation was performed with 145-175 kV and 0.5-5.0 mA at conveyor speeds between 2 and 20 cm/s, giving doses ranging from 5 to 500 kGy.

A grafting solution was prepared by vacuum distillation of styrene, which then was mixed with isopropanol in the proportion of 70:30 percent by volume in a reactor flask containing a stirring bar. The grafting solution was bubbled with nitrogen for at least half an hour. The irradiated samples were put into a reaction bottle under inert atmosphere. The grafting reaction was carried out under stirring at 80° C. for 2 hours. The grafted membranes were then Soxhlet extracted with chloroform. The degree of grafting (d.o.g.) was determined gravimetrically, d.o.g.=(m₂−m₁)/m₁*100% where m₁ is the mass of the original membrane and m₂ is the mass of the membrane after polystyrene grafting. The prepared membrane had 30% degree of grafting.

The membranes were immersed in 0.5 M chlorosulfonic acid in 1,2-dichloroethane at ambient temperature for 24 h. The sulfonated membranes were washed thoroughly with tetrahydrofuran and distilled water.

Organic field effect transistors Ta and Tb according to an embodiment of the invention were fabricated using ion-conductive polymer of the kind described above. The ion-conductivity is achieved with positively charged mobile ions. In the organic field effect transistor Ta, the channel length L, the channel width W, and the distance D between the gate and the channel are about 35 μm, 1.5 mm, and 100 μm, respectively. In the organic field effect transistor Tb, the channel length L, the channel width W, and the distance D between the gate and the channel are about 100 μm, 1.5 mm, and 100 μm, respectively.

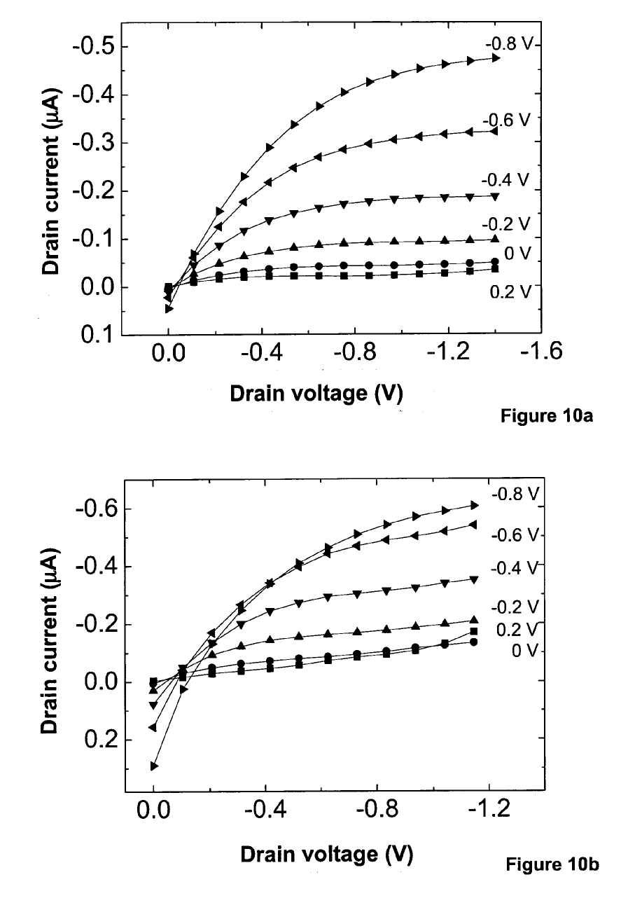

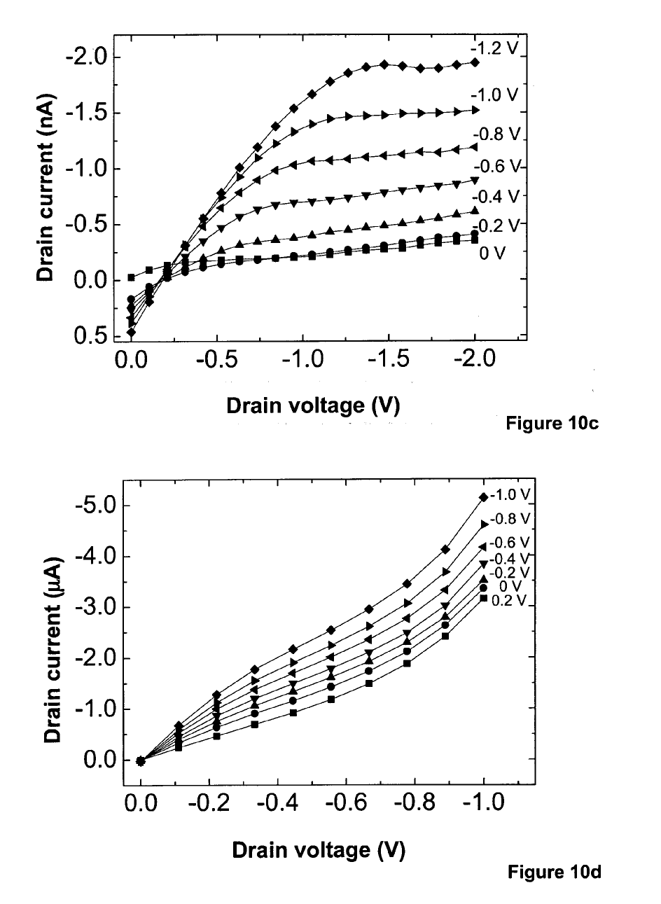

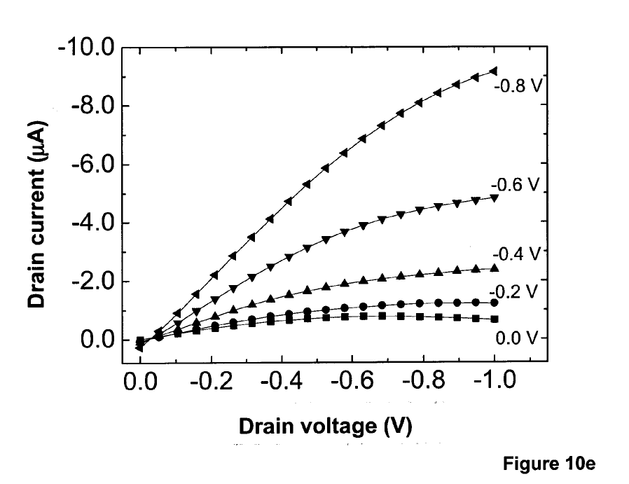

FIG. 10a shows measured dependencies of drain current on drain voltage for different gate voltages for the organic field-effect transistor Ta in anhydrous conditions. FIG. 10b shows measured dependencies of drain current on drain voltage for different gate voltages for the organic field-effect transistor Tb in hydrous conditions with 20% relative humidity.

### Example 2

In the second example a polymer membrane that exhibits ion-conductivity was produced otherwise in the same manner as in the first example but the grafting was carried out in the following way.

The grafting solution was prepared by vacuum distillation of vinylbenzene chloride (VBC), which then was mixed with toluene in the proportions 50:50 percent by volume in a reaction bottle. The grafting solution was bubbled with nitrogen for at least half an hour. The irradiated samples were put into the reaction bottle and the grafting reaction was carried out at 80° C. for about 24 hours. The grafted membranes were then Soxhlet extracted with chloroform. Then, the samples were dried to constant weight in a vacuum oven at 40° C., and weighed. The VBC-grafted PVDF membrane was soaked in reagent grade THF for 5 min and then immersed in a 45% aqueous solution of trimethylamine (Acros Organics) for 24 h. The reaction was carried out at 60° C. with nitrogen purged solution. It was observed at once that the membranes started to darken; after 24 h the membranes were weakly transparent with a dark brown coloration. After amination the membranes were washed with water several times and allowed to dry in air overnight. The prepared material had 30% degree of grafting (d.o.g., calculated from the mass gain on grafting).

An organic field effect transistor according to an embodiment of the invention was fabricated using ion-conductive polymer of the kind described above. The ion-conductivity is achieved with negatively charged mobile ions. FIG. 10c shows measured dependencies of drain current on drain voltage for different gate voltages for the organic field-effect transistor. The channel length L, the channel width W, and the distance D between the gate and the channel are about 100 μm, 1.5 mm, and 100 μm, respectively.

### Example 3

In the third example a polymer membrane that exhibits ion-conductivity was produced in the same manner as in the first example. The ion-conducting membrane was converted into a lithium ion-conducting membrane by immersing the film in 1M LiPF₆ in a 1:1 (v/v) mixture of ethylene carbonate (EC) and diethyl carbonate (DEC) until the equilibrium weight was achieved.

An organic field effect transistor according to an embodiment of the invention was fabricated using ion-conductive polymer of the kind described above. The ion-conductivity is achieved with positively charged mobile ions. FIG. 10d shows measured dependencies of drain current on drain voltage for different gate voltages for the organic field-effect transistor in anhydrous conditions. The channel length L, the channel width W, and the distance D between the gate and the channel are about 35 μm, 1.5 mm, and 100 μm, respectively.

### Example 4

In the fourth example a commercially available membrane (Nafion 115, Du Pont) was used as a polymer membrane that exhibits ion-conductivity. The ion-conductivity is achieved with positively charged mobile ions. FIG. 10e shows measured dependencies of drain current on drain voltage for different gate voltages for the organic field-effect transistor. The channel length L, the channel width W, and the distance D between the gate and the channel are about 35 μm, 1.5 mm, and 100 μm, respectively.

The invention is not limited merely to the embodiments and the experimental examples described above, many variants being possible without departing from the scope of the inventive idea defined in the independent claims.

1-53. (canceled)

54. An organic field-effect transistor comprising:
a source electrode (201) and a drain electrode (202),
an organic semiconductor layer (203) disposed to form a channel region between the source electrode and the drain electrode, and
a gate electrode (204),
characterized in that the organic field-effect transistor comprises between the organic semiconductor layer and the gate electrode a polymer membrane (205) that exhibits ion-conductivity between the channel region and the gate electrode and is capable of constituting a mechanical support of the organic field-effect transistor.

55. An organic field-effect transistor according to claim 54, characterised in that the organic semiconductor layer (203) is made of RR—P3HT (regioregular poly(3-hexylthiophene)).

56. An organic field-effect transistor according to claim 54, characterised in that the source electrode (201) and the drain electrode (202) are made of thin metal films.

57. An organic field-effect transistor according to claim 54, characterised in that the source electrode (201) and the drain electrode (202) are made of doped PANI (polyaniline).

58. An organic field-effect transistor according to claim 54, characterised in that the gate electrode (204) is made of PEDOT:PSS (poly(2,3-dihydrothieno-[3,4-b]-1,4-dioxin) and poly(styrenesulfonate)).

59. An organic field-effect transistor according to claim 54, characterised in that the gate electrode (204) is made of doped PANI (polyaniline).

60. An organic field-effect transistor according to claim 54, characterised in that the gate electrode (204) is made of a thin metal film.

61. An organic field-effect transistor according to claim 54, characterised in that a spatial area (206) that exhibits said ion-conductivity is disposed to extend through the polymer membrane (205).

62. An organic field-effect transistor according to claim 54, characterised in that there is an insulating spatial area of the polymer membrane between the gate electrode (403, 704) and a spatial area that exhibits said ion-conductivity (401, 702) of the polymer membrane.

63. An organic field-effect transistor according to claim 54, characterised in that there is an insulating spatial area of the polymer membrane between the organic semiconductor layer (503, 705) and a spatial area (501, 702) that exhibits said ion-conductivity of the polymer membrane.

64. An organic field-effect transistor according to claim 54, characterised in that a spatial area (206, 401, 501) that exhibits said ion-conductivity of the polymer membrane is surrounded by insulating spatial areas of the polymer membrane (205, 402, 502) in directions that are in a plane of the polymer membrane.

65. An organic field-effect transistor according to claim 54, characterised in that a spatial area (601) that exhibits said ion-conductivity of the polymer membrane is disposed to be within a coverage area of the channel region (604) in directions that are in a plane of the polymer membrane (607).

66. An organic field-effect transistor according to claim 54, characterised in that a whole volume of the polymer membrane (701) is ion-conductive.

67. An organic field-effect transistor according to claim 54, characterised in that the source electrode (801) and the drain electrode (802) are disposed to be between the organic semiconductor layer (804) and insulating spatial areas of the polymer membrane (803).

68. An organic field-effect transistor according to claim 54, characterised in that said ion-conductivity is achieved with positively charged mobile ions.

69. An organic field-effect transistor according to claim 54, characterised in that said ion-conductivity is achieved with negatively charged mobile ions.

70. An organic field-effect transistor according to claim 54, characterised in that said ion-conductivity is proton conductivity such that negatively charged anions are covalently linked to a molecular structure of the polymer membrane and positively charged H+ ions are mobile.

71. An organic field-effect transistor according to claim 54, characterised in that material of which the organic semiconductor layer (203) is formed is a polyfluorene derivative.

72. An organic field-effect transistor according to claim 71, characterised in that the polyfluorene derivative is poly(9,9-dioctylfluorene-co-bithiophene) alternating copolymer (F8T2).

73. An organic field-effect transistor according to claim 71, characterised in that the polyfluorene derivative is poly[2,7-(9,9-di-n-octylfluorene)-alt-(1,4-phenylene-((4-sec-butylphenyl)amino)-1,4-phenylene)] (TFB).

74. An organic field-effect transistor according to claim 54, characterised in that the organic semiconductor layer (203) is optically transparent with a band gap larger than 2.3 eV.

75. An organic field-effect transistor according to claim 54, characterised in that the organic semiconductor layer (203) has an ionization potential larger than 4.9 eV.

76. An organic field-effect transistor according to claim 54, characterised in that the organic semiconductor layer (203) has an ionization potential larger than 5.1 eV.

77. An organic field-effect transistor according to claim 54, characterised in that the organic semiconductor layer (203) comprises a block copolymer comprising a first block of conjugated monomer units each linked by at least two covalent bonds, and a second block of monomer units, the block copolymer having an electron affinity greater than 3.0 eV.

78. An organic field-effect transistor according to claim 54, characterised in that the organic semiconductor layer (203) comprises a block copolymer comprising a first block of conjugated monomer units each linked by at least two covalent bonds, and a second block of monomer units, the block copolymer having an ionization potential in the range from 5.5 eV to 4.9 eV.

79. An organic field-effect transistor according to claim 54, characterised in that the polymer membrane (205) is paper impregnated with ion-conducting liquid.

80. An organic field-effect transistor according to claim 54, characterised in that the polymer membrane (205) is paper made of sulfonated natural fibers.

81. An organic field-effect transistor according to claim 54, characterised in that the organic field-effect transistor comprises an ion-blocking layer (806) between the gate electrode (805) and the polymer membrane (803).

82. An organic field-effect transistor according to claim 54, characterised in that the organic field-effect transistor comprises an ion-blocking layer (807) between the organic semiconductor layer (804) and the polymer membrane (803).

83. An organic field-effect transistor according to claim 54, characterised in that the organic field-effect transistor comprises a first ion-blocking layer (806) between the gate electrode (805) and the polymer membrane (803), and a second ion-blocking layer (807) between the organic semiconductor layer (804) and the polymer membrane (803).

84. A method for manufacturing an organic field-effect transistor, characterised in that the method comprises:
fabricating (901) a polymer membrane at least a part of which exhibits ion-conductivity and which is capable of constituting a mechanical support of the organic field-effect transistor,
forming (902) an organic semiconductor layer on a first side of the polymer membrane, and
forming (903) a gate electrode on a second side of said polymer membrane to cover at least partly a projection of an ion-conductive spatial area of said polymer membrane, said projection being on a surface of the polymer membrane.

85. A method according to claim 84, characterised in that it comprises forming another organic semiconductor layer and forming another gate electrode for manufacturing another organic field-effect transistor onto the polymer membrane.

86. A method according to claim 84, characterised in that it comprises forming (905) a source electrode and a drain electrode on a surface of the organic semiconductor layer.

87. A method according to claim 84, characterised in that it comprises forming (904) a source electrode and a drain electrode on a surface of the polymer membrane on the first side of the polymer membrane.

88. A method according to claim 84, characterised in that it comprises applying a printing technique with a polymer solution in order to form at least one of the following: the organic semiconductor layer, the gate electrode, a drain electrode, and a source electrode.

89. A method according to claim 84, characterised in that said ion-conductivity is achieved with positively charged mobile ions.

90. A method according to claim 84, characterised in that said ion-conductivity is achieved with negatively charged mobile ions.

91. A method according to claim 84, characterised in that the fabricating (901) the polymer membrane involves homopolymerizing or copolymerizing a monomer containing an ion exchange group with non-functionalized monomer.

92. A method according to claim 84, characterised in that the fabricating (901) the polymer membrane involves modifying polymer particles by introducing ion exchange groups and embedding said modified polymer particles in a polymer binder.

93. A method according to claim 84, characterised in that the fabricating (901) the polymer membrane involves modifying a film by grafting of functional monomer.

94. A method according to claim 84, characterised in that the fabricating (901) the polymer membrane involves modifying a film by grafting of non-functional monomer followed by a functionalization reaction.

95. A method according to claim 84, characterised in that the fabricating (901) the polymer membrane involves blending of various polymers by acid-base blending.

96. A method according to claim 84, characterised in that the fabricating (901) the polymer membrane involves producing a membrane of organic-inorganic composites.

97. A method according to claim 84, characterised in that the fabricating (901) the polymer membrane involves using porous polymer films that are impregnated with ion-conducting liquid.

98. A method according to claim 84, characterised in that the fabricating (901) the polymer membrane involves adjusting said ion-conductivity to a desired value by regulating a concentration of fixed ions and their locations.

99. A method according to claim 84, characterised in that the fabricating (901) the polymer membrane involves adjusting said ion-conductivity to a desired value by using acid.

100. A method according to claim 84, characterised in that said ion-conductivity is proton conductivity such that negatively charged anions are covalently linked to a molecular structure of the polymer membrane and positively charged H+ ions are mobile.

101. A method according to claim 100, characterised in that the fabricating (901) the polymer membrane involves radiating a poly(vinylidene fluoride)-membrane with electron beams and quenching free radicals with 2,2,6,6-tetramethyl-piperidinyl-1-oxy, utilizing produced 2,2,6,6-tetramethyl-piperidinyl-1-oxy-capped macroinitiator sites in nitroxide-mediated living free radical graft polymerization of styrene onto the poly(vinylidene fluoride)-membrane, and sulfonating the poly(vinylidene fluoride)-membrane.

102. A method according to claim 100, characterised in that the fabricating (901) the polymer membrane involves sulfochlorination of a bulk polymer with subsequent hydrolysis.

103. A method according to claim 102, characterised in that said bulk polymer is polyethylene (PE).

104. A method according to claim 100, characterised in that the fabricating (901) the polymer membrane involves radiation grafting of a bulk polymer with gamma-ray irradiation.

105. A method according to claim 100, characterised in that the fabricating (901) the polymer membrane involves adjusting said proton conductivity to a desired value by regulating a concentration of fixed ions and their locations.

106. A method according to claim 100, characterised in that the fabricating (901) the polymer membrane involves adjusting said proton conductivity to a desired value by using acid.
